(19) United States
(12) Patent Application Publication
(10) Pub. No.: US 2010/0116788 A1
(43) Pub. Date: May 13, 2010

(54) Substrate temperature control by using liquid controlled multizone substrate support

(75) Inventors: Harmeet Singh, Fremont, CA (US); Keith Comendant, Fremont, CA (US)

Correspondence Address: BUCHANAN, INGERSOLL & ROONEY PC, POST OFFICE BOX 1404, ALEXANDRIA, VA, 22313-1404, US

(73) Assignee: Lam Research Corporation, Fremont, CA (US)

(21) Appl. No.: 12/292,081

(22) Filed: Nov. 12, 2008

(51) Int. Cl. B44C 1/22; C23F 1/08; C23C 16/54; C23C 14/22; C23C 14/34

(52) U.S. Cl. 216/66; 156/345.52; 118/723 R; 204/298.09; 156/345.24; 118/663; 427/523; 427/585; 204/192.1

(57) ABSTRACT

A substrate support useful in a reaction chamber of a plasma processing apparatus is provided. The substrate support comprises a base member and a heat transfer member overlying the base member. The heat transfer member has multiple zones to individually heat and cool each zone of the heat transfer member. An electrostatic chuck overlies the heat transfer member. The electrostatic chuck has a support surface for supporting a substrate in a reaction chamber of the plasma processing apparatus. A source of cold liquid and a source of hot liquid are in fluid communication with flow passages in each zone. A valve arrangement is operable to independently control temperature of the liquid by adjusting a mixing ratio of the hot liquid to the cold liquid circulating in the flow passages. In another embodiment, heating elements along a supply line and transfer lines heat a liquid from a liquid source before circulating in the flow passages.

### BACKGROUND

Plasma processing apparatuses are used to process substrates by techniques including etching, physical vapor deposition (PVD), chemical vapor deposition (CVD), ion implantation, and resist removal. One type of plasma processing apparatus used in plasma processing includes a reaction chamber containing top and bottom electrodes. An electric field is established between the electrodes to excite a process gas into the plasma state to process substrates in the reaction chamber. Due to shrinking feature sizes and the implementation of new materials, improvement in plasma processing apparatuses to control the conditions of the plasma processing is required.

### SUMMARY

In one embodiment, a substrate support useful in a reaction chamber of a plasma processing apparatus is provided. The substrate support comprises a base member and a heat transfer member overlying the base member. The heat transfer member has multiple zones including at least a first zone with a first flow passage therein and a second zone with a second flow passage therein through which a liquid can be circulated to individually heat and cool the first and second zones of the heat transfer member. An electrostatic chuck overlies the heat transfer member. The electrostatic chuck has a support surface for supporting a substrate in a reaction chamber of the plasma processing apparatus. A source of cold liquid and a source of hot liquid are in fluid communication with the first and second flow passages. A valve arrangement is operable to independently control temperature of the liquid in the first and second zones by adjusting a mixing ratio of the hot liquid to the cold liquid circulating in the first and second flow passages. A controller controls the valve arrangement to independently control the temperature in the first and second zones by adjusting the mixing ratio of the hot liquid to the cold liquid in the first and second flow passages.

In another embodiment, a method of controlling a temperature of a semiconductor substrate during plasma processing is provided. The substrate is supported on the substrate support, described above, and in thermal contact with the multiple zones. In the method, liquid flows through the first and second flow passages, a temperature of the first zone is measured, and the temperature of the liquid flowing through the first flow passage is: (a) increased if the temperature of the first zone is below a target temperature by increasing the mixing ratio of the hot liquid to the cold liquid; or (b) decreased if the temperature of the first zone is above the target temperature by decreasing the mixing ratio of the hot liquid to the cold liquid. Likewise, a temperature of the second zone is measured and the temperature of the liquid flowing through the second flow passage is: (a) increased if the temperature of the second zone is below a target temperature by increasing the mixing ratio of the hot liquid to the cold liquid; or (b) decreased if the temperature of the second zone is above the target temperature by decreasing the mixing ratio of the hot liquid to the cold liquid. Preferably, an azimuthal temperature difference within each zone is less than 5° C.

In another embodiment, a substrate support useful in a reaction chamber of a plasma processing apparatus is provided. The substrate support comprises a base member and a heat transfer member overlying the base member. The heat transfer member has a first zone with a first flow passage and a second zone with a second flow passage. The flow passages are adapted to circulate a liquid to individually heat and cool each zone of the heat transfer member. A first common line is in fluid communication with the first flow passage and a second common line is in fluid communication with the second flow passage. A first valve is in fluid communication with the first common line and a first supply line from a hot liquid source. The first valve is operable to control an amount of flow of a hot liquid from the hot liquid source through the first common line. A second valve is in fluid communication with the first common line and a second supply line from a cold liquid source. The second valve is operable to control an amount of flow of a cold liquid from the cold liquid source through the first common line. A third valve is in fluid communication with the second common line and the first supply line from the hot liquid source. The third valve is operable to control an amount of flow of the hot liquid through the second common line. A fourth valve is in fluid communication with the second common line and the second supply line from the cold liquid source. The fourth valve is operable to control an amount of flow of the cold liquid through the second common line. A controller is operable to independently control the first valve and the second valve to adjust a first mixing ratio of the hot liquid to the cold liquid to the first flow passage; and the third valve and the fourth valve to adjust a second mixing ratio of the hot liquid to the cold liquid to the second flow passage. An electrostatic chuck overlies the heat transfer member. The electrostatic chuck has a support surface for supporting a substrate in a reaction chamber of the plasma processing apparatus.

In another embodiment, a substrate support useful in a reaction chamber of a plasma processing apparatus is provided. The substrate support comprises a base member and a heat transfer member overlying the base member. The heat transfer member has a first zone with a first flow passage therein and a second zone with a second flow passage therein. The flow passages are adapted to circulate a liquid to individually heat and cool each zone of the heat transfer member. A supply line is in fluid communication with the first flow passage and a liquid source. A first heating element is along the supply line. The first heating element is adapted to heat the liquid flowing from the liquid source to a first temperature before the liquid is circulated in the first flow passage. A first transfer line is in fluid communication with the first flow passage and the second flow passage. The first transfer line is adapted to flow the liquid from the first flow passage to the second flow passage. A second heating element is along the first transfer line. The second heating element is adapted to heat the liquid to a second temperature before circulating in the second flow passage. A controller controls each heating element to independently control the temperature of each zone by adjusting power to each heating element. An electrostatic chuck overlies the heat transfer member. The electrostatic chuck has a support surface for supporting a substrate in a reaction chamber of the plasma processing apparatus.

### BRIEF DESCRIPTION OF FIGURES

FIG. 1 is a cross-sectional view of an exemplary embodiment of a plasma processing apparatus.

FIG. 2 is a cross-sectional view of an inductively coupled plasma processing apparatus.

FIG. 3 is a cross-section view of one embodiment of a substrate support.

FIG. 4 is a cross-section view of an additional embodiment of a substrate support including thermal barriers extending through a partial thickness of the heater transfer member.

FIG. 5 is a cross-section view of an additional embodiment of a substrate support with no thermal barriers.

FIG. 6 is a sectional plan view of the support of FIG. 3, taken along sectional line C-C′.

FIG. 7 is a partial cross-sectional view of one embodiment of a heat transfer member, including a source of cold liquid, a source of hot liquid, a valve arrangement and a controller.

FIG. 8A is a partial cross-sectional view of another embodiment of a heat transfer member, including a source of cold liquid, a source of hot liquid, a valve arrangement and a controller.

FIG. 8B is a partial cross-sectional view of the embodiment of the heat transfer member of FIG. 8A, including a return line to the source of cold liquid and/or the source of hot liquid.

FIG. 9 is a partial cross-sectional view of another embodiment of a heat transfer member, including a source of liquid, heating elements and transfer lines.

FIG. 10 illustrates three exemplary center-to-edge temperature profiles of a semiconductor substrate during plasma processing.

### DETAILED DESCRIPTION

In order to enhance the uniformity of plasma processing of a substrate in a plasma processing apparatus, it is desirable to control the temperature distribution at an exposed surface of the substrate where material deposition and/or etching occurs. In plasma etching processes, variations in the substrate temperature and/or in rates of chemical reaction at the substrate's exposed surface can cause undesirable variations in the etching rate of the substrate, as well as in etch selectivity and anisotropy. In material deposition processes, such as CVD processes, the deposition rate and the composition and properties of material deposited on the substrate can be significantly affected by the temperature of the substrate during deposition.

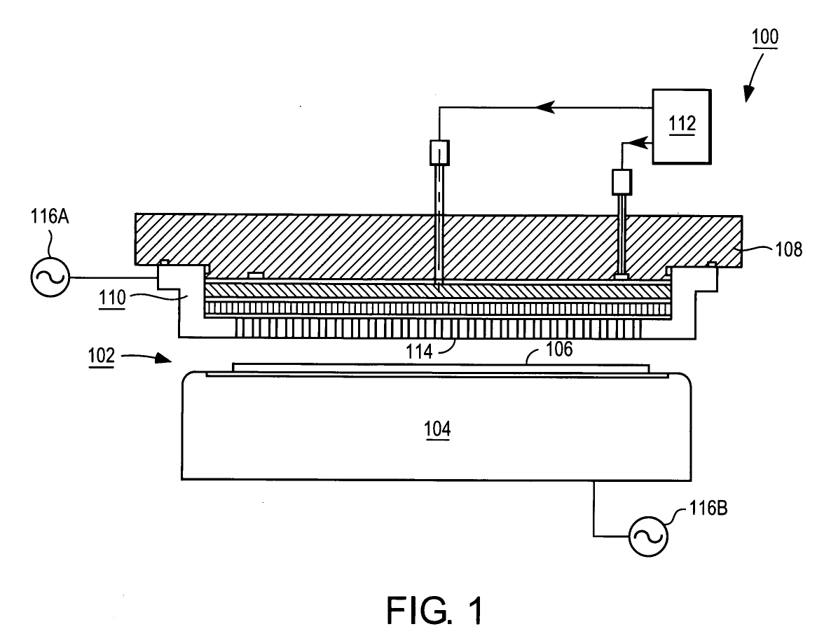

FIG. 1 illustrates an exemplary semiconductor material plasma processing apparatus 100 for etching. Plasma processing apparatus 100 comprises a reaction chamber 102 containing a substrate support 104 on which a substrate 106 is supported during plasma processing. The substrate support 104 for supporting a substrate 106 in the interior of the reaction chamber 102 can include a clamping device, preferably an electrostatic chuck, which is operable to clamp the substrate 106 on the substrate support 104 during processing.

The exemplary plasma process apparatus 100 shown in FIG. 1 includes a showerhead electrode assembly having a top plate 108 forming a wall of the reaction chamber 102 and a showerhead electrode 110 attached to the top plate 108. Gas supply 112 supplies process gas to the interior of the reaction chamber 102, via showerhead electrode 110. Showerhead electrode 110 includes multiple gas passages 114 extending through the thickness of the showerhead electrode 110 for injecting process gas into a space in a plasma reaction chamber 102 located between showerhead electrode 110 and the substrate support 104. The gas supply 112 can include inner and outer supply lines feeding the center and outer zones of the showerhead electrode 110 in a dual zone gas feed arrangement.

The process gas flows through showerhead electrode 110 and into the interior of the reaction chamber 102. Next, the process gas is energized into the plasma state in the plasma process apparatus 100 by a power source 116A, such as an RF source driving showerhead electrode 110, and/or a power source 116B at one or more frequencies from about 0.3 to about 600 MHz (e.g., 2 MHz, 13.56 MHz, 60 MHz) driving an electrode in the substrate support 104 at one or more frequencies from about 0.3 to about 600 MHz (e.g., 2 MHz, 13.56 MHz, 60 MHz). The RF power applied to the showerhead electrode 110 can be changed to perform different process steps such as when different gas compositions are supplied into the plasma process apparatus 100. In another embodiment, showerhead electrode 110 can be grounded.

In one embodiment, the plasma can be generated in the interior of plasma process apparatus 100 by supplying RF energy from two RF sources to the showerhead electrode 110 and/or the substrate support 104, or the showerhead electrode 110 can be electrically grounded and RF energy at a single frequency or multiple frequencies can be supplied to the substrate support 104.

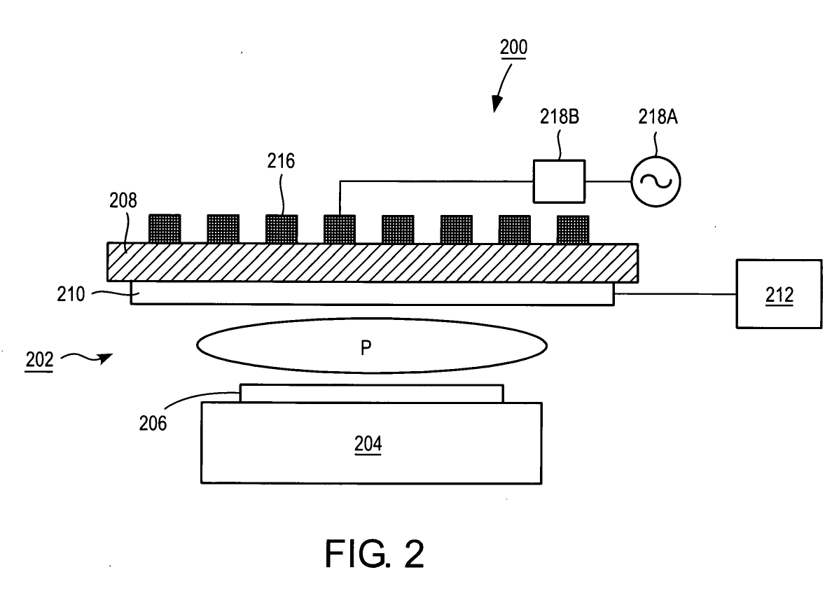

In another embodiment, as illustrated in FIG. 2, inductively coupled plasma (ICP) processing apparatus 200 can be used for depositing (e.g., plasma enhanced chemical vapor deposition or PECVD) and plasma etching of materials on substrates by supplying process gas into a vacuum chamber at a low pressure (i.e., below 100 mTorr) and the application of radio-frequency (RF) energy to the gas. FIG. 2 is a cross-sectional view of an embodiment of an ICP plasma processing apparatus 200. An example of an ICP plasma processing chamber is the TCP® etch or deposition system, manufactured by Lam Research Corporation, Fremont, Calif. The ICP plasma processing apparatus is also described, for example, in commonly-owned U.S. Pat. No. 4,948,458, which is incorporated by reference in its entirety. Reaction chamber 202 includes a substrate support 204 for supporting the substrate 206 in the interior of the reaction chamber 202. Dielectric window 208 forms a top wall of reaction chamber 202. Process gases are injected to the interior of the reaction chamber 202 through a gas distribution member 210. Examples of gas distribution member 210 include a showerhead, gas injector or other suitable arrangement. A gas supply 212 supplies process gases to the interior of reaction chamber 202 through gas distribution member 210.

Once process gases are introduced into the interior of reaction chamber 202, they are energized into a plasma state by an energy source 216 supplying energy into the interior of reaction chamber 202. Preferably, the energy source 216 is an external planar antenna powered by an RF source 218A and RF impedance matching circuitry 218B to inductively couple RF energy into reaction chamber 202. An electromagnetic field generated by the application of RF power to planar antenna energizes the process gas to form a high-density plasma P (e.g., 10¹⁰-10¹² ions/cm³) above substrate 206.

A dielectric window 208 underlies planar antenna and gas distribution member 210 is placed below dielectric window 208. Plasma P is generated in the zone between gas distribution member 210 and substrate 206, for either deposition or etching of substrate 206.

During plasma processing of substrates, the reactive ions of the plasma gas chemically react with portions of material on a face of the semiconductor substrate (e.g., a silicon, gallium arsenide or indium phosphide wafer), resulting in temperature differences of up to 50° C. between the center and edge of the substrate. Local substrate temperature and rate of chemical reaction at each point on the substrate are interrelated such that non-uniform etching or deposition of material over a face of the substrate can result if the temperature of the substrate across its face varies too much. To alleviate this condition, backside gas cooling systems have been used in substrate supports to provide heat transfer between the substrate support and substrates supported on the substrate support.

Substrate supports have included coolant flow passages to remove heat from the substrate support during processing. In such cooling systems, coolant at a controlled temperature and a set volumetric flow rate is introduced into the coolant flow passages. Substrate supports have included one supply line and one return line in the cooling system. However, it has been determined that as heat is removed from the substrate support, a significant temperature gradient can develop along the length of the passages, from the inlet to the outlet. As a result, the temperature uniformity at the surface of the substrate support in contact with the heat transfer gas and the substrate is not controlled. Substrate holders also provide a heat sink at the back side of the substrate. Resulting heat transfer from the substrate to the substrate holder has contributed to non-uniformity of temperature across the substrate in known plasma processing apparatuses.

The ability to vary the center-to-edge temperature profile (i.e., radial temperature profile) across a wafer or substrate by as much as 40° C., while maintaining an azimuthal (i.e., angular or circumferential) temperature uniformity ≦5° C. is essential for critical dimension uniformity control. Some plasma processing steps require radial temperature profile control for optimal processing to compensate for non-uniformity due to other factors such as etch by-product concentration variation as a function of radial position on the substrate. For example, during the etching of a stack of thin films or a multi-layer structures (e.g., gate oxide/polysilicon/silicide/hardmask/anti-reflective coating stack), the etching of one layer may require a center region hotter than an edge region, whereas the etching of another layer may require a center region colder than an edge region. Thus, a need exists for a substrate support with the ability to achieve an azimuthal temperature uniformity of ≦5C, with the ability vary the center-to-edge temperature profile across a wafer or substrate by as much as 40° C. Preferably, the azimuthal temperature uniformity is ≦1° C.; and more preferably the azimuthal temperature uniformity is ≦0.5° C.

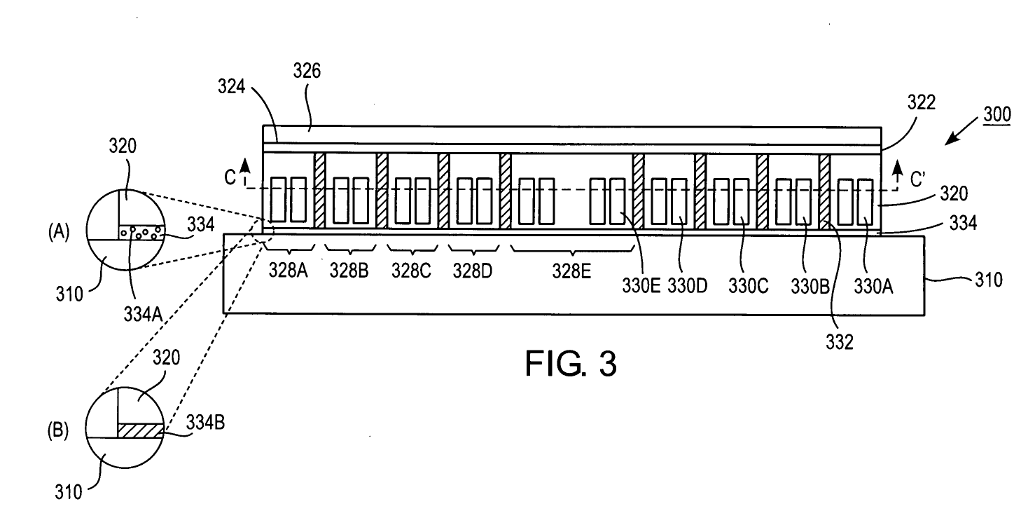

FIG. 3 illustrates a cross-section view of one embodiment of substrate support 300. Substrate 326 provides the ability to more effectively control center-to-edge temperature profile, which can be step-changeable for up to 40° C. center-to-edge temperature profile while maintaining azimuthal temperature uniformity of ≦1° C. Substrate support 300 includes base member 310, heat transfer member 320 overlying base member 310 and electrostatic chuck 322 overlying heat transfer member 320. Electrostatic chuck 322 includes a support surface 324 for supporting substrate 326. Such electrostatic chucks are also described, for example, in commonly-owned U.S. Pat. No. 5,838,529, which is incorporated by reference in its entirety.

Heat transfer member 320 is further subdivided into concentric multiple zones 328A-328E. Each zone contains one or more flow passages 330A-330E, through which liquid can be circulated to individually heat and cool each zone 328A-328E of heat transfer member 320. Heating of the substrate support 300 is achieved by circulating a hot liquid through flow passages 330A-330E, thus eliminating the need for a heating element (e.g., resistive heater or heating tape) embedded in the heat transfer member 320. The liquid can be water (e.g., deionized water), ethylene glycol, silicon oil, water/ethylene glycol mixtures, FLUOROINERT® refrigerant (i.e., perfluorocarbon cooling fluid, available from Minnesota Mining and Manufacturing (3M) Company), GALDEN® fluids (i.e., low molecular weight perfluoropolyether heat transfer fluid, available from Solvay Solexis) and the like. Although five zones are illustrated in FIG. 3, it is understood that the number of zones can be two or more, depending on the degree of temperature controlled desired.

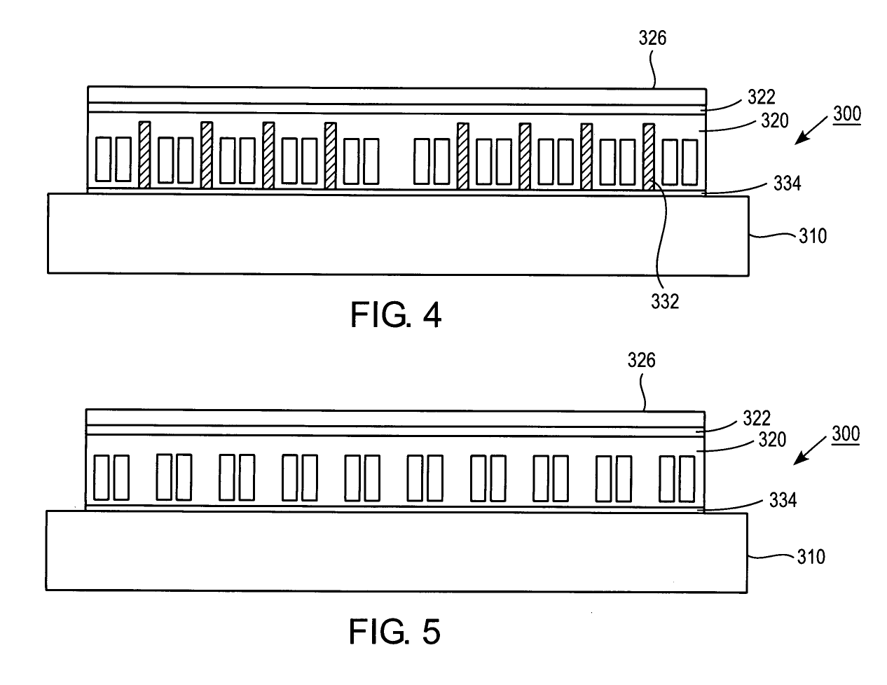

In the embodiment of FIG. 3, heat transfer member 320 can be composed of a thermally conductive material, such as aluminum or aluminum nitride. To improve control of radial heat transfer (i.e., heat transfer between individual zones) and to achieve a desired temperature profile across a substrate, thermal barriers 332 separate each zone 328A-328E. Thermal barriers 332 can either extend through an entire thickness of heat transfer member 320 (as illustrated in FIG. 3) or through a partial thickness of heat transfer member 320, as illustrated in FIG. 4. Thermal barriers 332 can either be unfilled (i.e., an empty space) or contain a filler material to achieve a thermal conductivity from about 0.1 W/m-K to about 4.0 W/m-K. Examples of filler materials include epoxy or silicone. Thermal conductivity of the filler material can be adjusted using additives such as boron nitride, aluminum nitride, aluminum oxide, silicon oxide, and silicon.

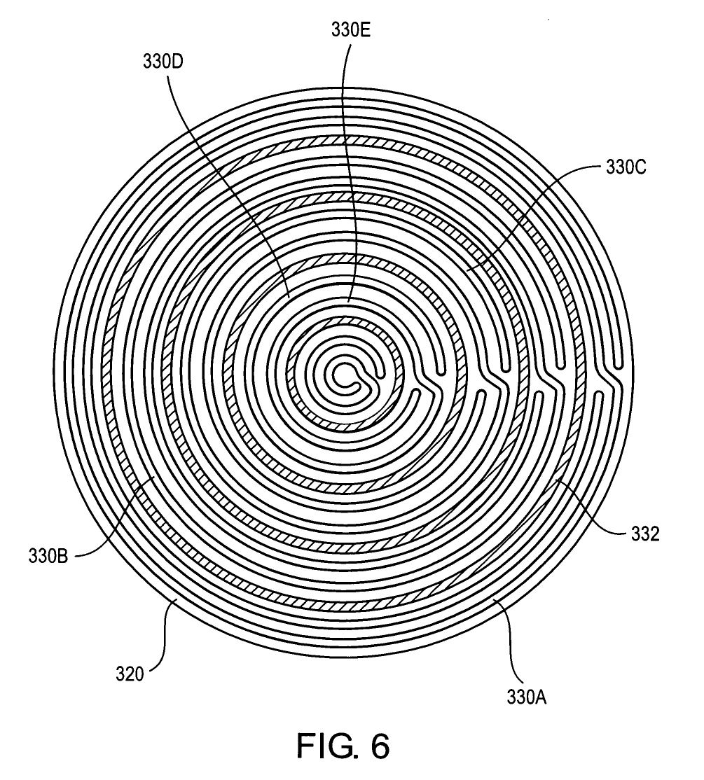

In another embodiment, as illustrated in FIG. 5, radial heat transfer is controlled by composing heat transfer member 320 of a thermally insulating material. Examples of thermally insulating materials include ceramics such as aluminum oxide or yttrium oxide; or metal alloys with a lower thermal conductivity, such as stainless steel.

As illustrated in FIG. 3, bonding material 334 can be inserted between heat transfer member 320 and base member 310. Bonding material 334 can be composed of epoxy or silicone, which can be filled with one or more filler materials 334A, as illustrated in enlarged region A. Exemplary filler materials 334A can include aluminum oxide, boron nitride, silicon oxide, aluminum or silicon. In another embodiment, illustrated in enlarged region B, bonding material can be a metallic braze 334B. Bonding material 334 can be selected to provide a thermal conductivity from about 0.1 W/m-K to about 4 W/m-K and have a thickness from about 1 mil to about 200 mils.

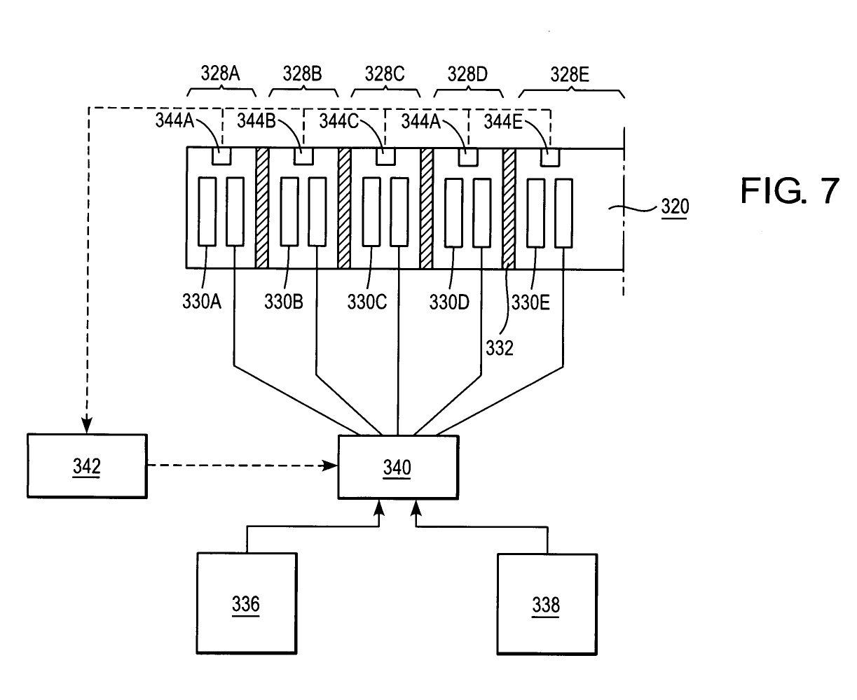

FIG. 6 illustrates a sectional plan view of heat transfer member 320 as a circular plate, taken across sectional line C-C′ from FIG. 3. From FIG. 6, zones 328A-328E are concentrically arranged at different distances relative to the center of a circular plate and flow passages 330A-330E have a spiral-like pattern. Thermal barriers 332 are annular channels separating each zone.

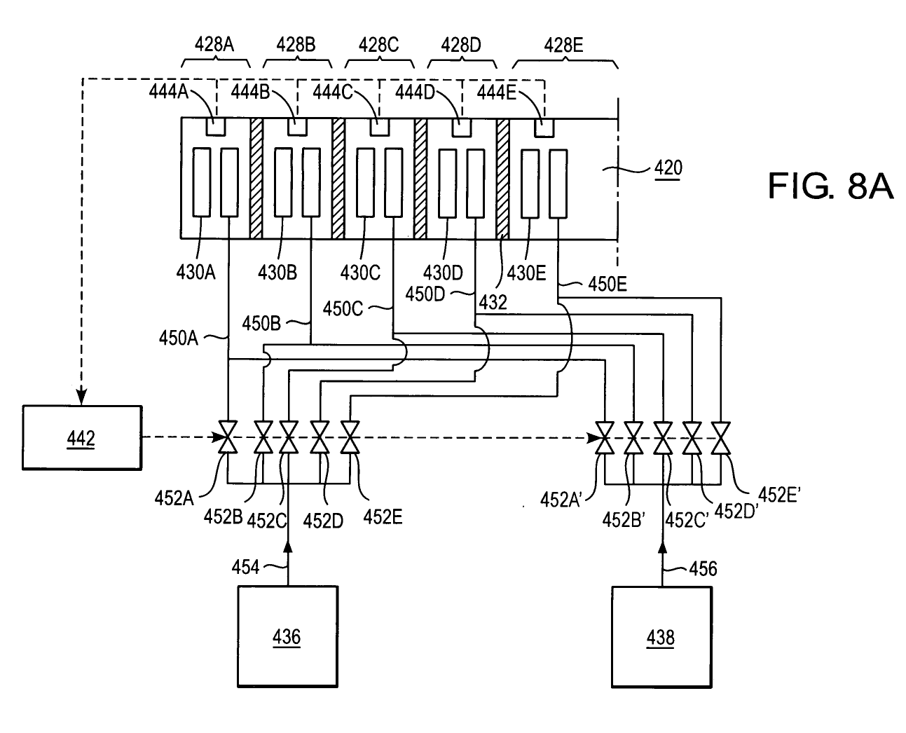

FIG. 7 illustrates a partial cross-sectional view of heat transfer member 320, including a source of hot liquid 336 and a source of cold liquid 338, both sources being in fluid communication with flow passages 330A-330E. Zones 328A-328E are separated by thermal barriers 332. Valve arrangement 340 is operable to control the individual temperature in each zone 328A-328E by adjusting a mixing ratio of hot liquid (from source of hot liquid 336) to cold liquid (from source of cold liquid 338). Controller 342 receives input signals from temperature sensors 344A-344E in each zone 328A-328E to independently direct valve arrangement 340 to adjust the appropriate mixing ratio of hot liquid to cold liquid. In another embodiment, temperature sensors for each zone 328A-328E can be embedded in the electrostatic chuck 322.

During plasma processing, substrate 326 is supported on substrate support 300, with the substrate 326 in thermal contact with zones 328A-328E. A liquid flows through flow passages 330A-330E, corresponding to zones 328A-328E. The temperature of each individual zone 328A-328E is measured with temperature sensors 344A-344E, which provide input signals to controller 342. Controller 342 can either: (i) increase the temperature of the liquid flowing through each individual flow passage 330A-330E if the temperature of a zone 328A-328E is below a target temperature by increasing the mixing ratio of hot liquid to cold liquid; or (ii) decrease the temperature of the liquid flowing through each individual flow passage 330A-330E if the temperature of a zone 328A-328E is above a target temperature by decreasing the mixing ratio of hot liquid to cold liquid. During plasma processing, substrate support 300 with heat transfer member 320 and controller 342 provides the ability to independently and dynamically change temperatures of zones 328A-328E during a plasma processing of a single wafer.

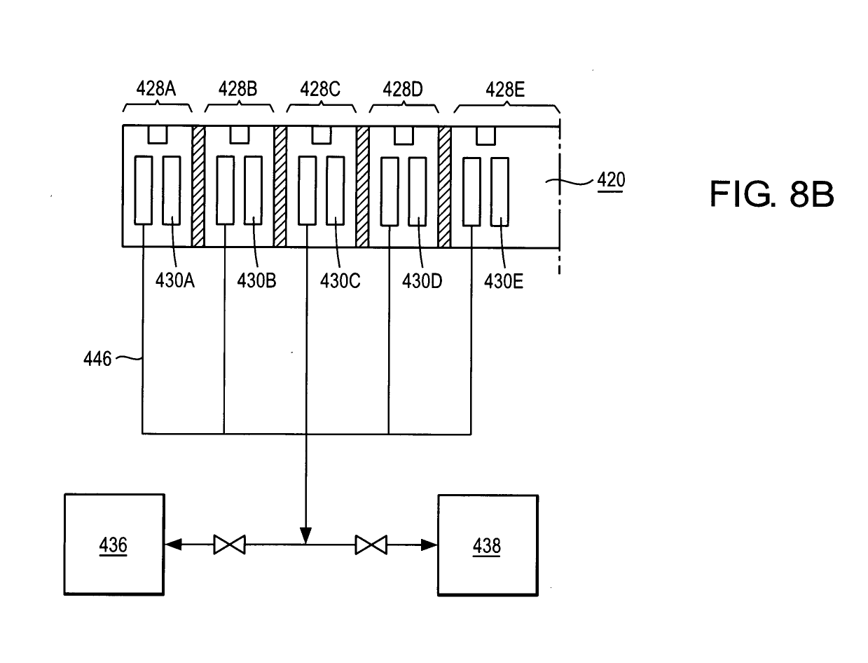

FIG. 8A illustrates a partial cross-sectional view for another embodiment of heat transfer member 420, including zones 428A-428E, each zone having respective flow passage 430A-430E and temperature sensor 444A-444E. Zones 428A-428E are separated by thermal barriers 432. A source of hot liquid 436 and a source of cold liquid 438 are in fluid communication with flow passages 430A-430E, via common lines 450A-450E, valves 452A-452E′, first supply line 454 and second supply line 456. First through fifth valves 452A-452E are in fluid communication with common lines 450A-450E and first supply line 454, which supplies hot liquid from hot liquid source 436. Additionally, sixth through tenth valves 452A′-452E′ are also in fluid communication with common lines 450A-450E and second supply line 456, which supplies cold liquid from cold liquid source 438.

Controller 442 receives input signals from temperature sensors 444A-444E to independently control valves 452A-452E and 452A′-452E′ for individually adjusting a mixing ratio of hot liquid flowing from hot liquid source 436 to cold liquid flowing from cold liquid source 438 in each flow passage. For example, controller 442 can control: (i) first valve 452A and second valve 452A′ to adjust a first mixing ratio of hot liquid to cold liquid flowing through common line 450A to flow passage 430A; (ii) third valve 452B and fourth valve 452B′ to adjust a second mixing ratio of hot liquid to cold liquid flowing through common line 450B to flow passage 430B; (iii) fifth valve 452C and sixth valve 452C′ to adjust a third mixing ratio of hot liquid to cold liquid flowing through common line 450C to flow passage 430C; (iv) seventh valve 452D and eighth valve 452D′ to adjust a fourth mixing ratio of hot liquid to cold liquid flowing through common line 450D to flow passage 430D; and (v) ninth valve 452E and tenth valve 452E′ to adjust a fifth mixing ratio of hot liquid to cold liquid flowing through common line 450E to flow passage 430E.

The FIG. 8A embodiment provides the ability to monotonically (i.e., successive increasing or decreasing in temperature) or non-monotonically increase or decrease temperature along a radius of substrate 426 during plasma processing, by controlling the temperature of each individual zone 428A-428E. For example, the temperature in each individual zone 428A-428E can be set such that the radial temperature profile is parabolic or inverse parabolic (i.e. monotonic). However, because the temperature in each zone 428A-428E can be individually controlled, in another example, the radial temperature profile can also be set such that the radial temperature profile is sinusoidal (i.e. non-monotonic).

As illustrated in FIG. 8B, flow passages 430A-430E are in fluid communication with return line 446, which is in fluid communication with source of hot liquid 436 and/or source of cold liquid 438. The liquid exiting flow passages 430A-430E can thus be recycled by returning the liquid to the source of hot liquid 436 and/or source of cold liquid 438.

The source of hot liquid 436 maintains the hot liquid at a temperature from about 40° C. to about 150° C.; the source of cold liquid 438 can maintain the cold liquid at a temperature from about −10° C. to about 70° C. Thus, the embodiment of FIGS. 8A and 8B has the capability of achieving five different temperatures in each zone 428A-428E, depending upon a desired center-to-edge temperature profile during plasma processing. Although five zones are illustrated in FIGS. 8A and 8B, it is understood that the number of zones can be two or more, depending on the degree of radial temperature profile control desired. In one example, the source of cold liquid maintains the cold liquid at a temperature ≧−10° C.; and the source of hot liquid maintains the hot liquid at a temperature ≦150° C., with the hot liquid temperature being greater than the cold liquid temperature.

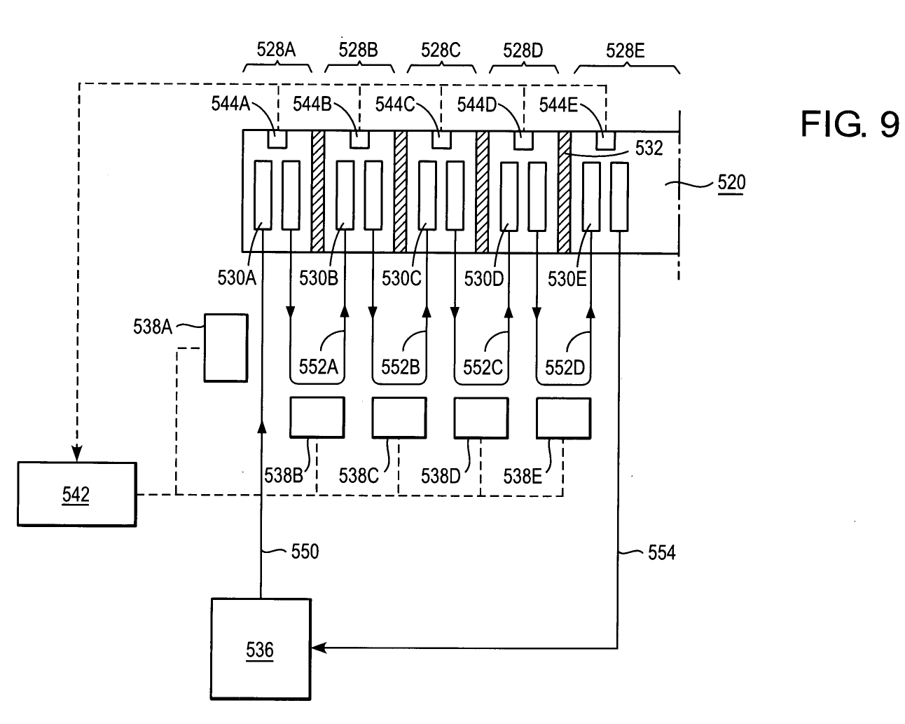

FIG. 9 illustrates a partial cross-sectional view for another embodiment of heat transfer member 520, including zones 528A-528E, each zone having respective flow passages 530A-530E and temperature sensors 544A-544E. Zones 528A-528E are separated by thermal barriers 532. A source of liquid 536 is in fluid communication with supply line 550, first through fourth transfer lines 552A-552D and return line 554. First heating element 538A is positioned along supply line 550; and second through fifth heating elements 538B-538E are positioned along first through fourth transfer lines 552A-552D. First through fifth heating elements 538A-538E control the temperature of the liquid flowing through supply line 550 and first through fourth transfer lines 552A-552D.

Controller 542 receives input signals from temperature sensors 544A-554E to independently control heating elements 538A-538E. If a temperature measured by temperature sensors 544A-544E is below a target temperature, controller 542 activates one or more of the appropriate heating elements 538A-538E. First heating element 538A heats liquid flowing from liquid source 536 to a first temperature before the liquid is circulated in first flow passage 530A. First transfer line 552A flows liquid from first flow passage 530A to second flow passage 530B; and second heating element 538B heats liquid flowing along the first transfer line 552A to a second temperature before circulating in the second flow passage 530B. Second transfer line 552B flows liquid from second flow passage 530B to third flow passage 530C; and third heating element 538C heats liquid flowing along the second transfer line 552B to a third temperature before circulating in the third flow passage 530C. Third transfer line 552C flows liquid from third flow passage 530C to fourth flow passage 530D; and fourth heating element 538D heats liquid flowing along the third transfer line 552C to a fourth temperature before circulating in the fourth flow passage 530D. Fourth transfer line 552D flows liquid from fourth flow passage 530D to fifth flow passage 530E; and fifth heating element 538E heats liquid flowing along the fourth transfer line 552D to a fifth temperature before circulating in the fifth flow passage 530E. Liquid exiting fifth flow passage is returned to the liquid source 536 along return line 554.

Liquid flowing through first through fourth transfer lines 552A-552D can either flow in a forward direction (as indicated by the arrows in FIG. 9) or a reverse direction (not indicated in FIG. 9). During liquid flow in the forward direction, the first temperature is less than the second temperature, which is less than the third temperature, which is less than the fourth temperature, resulting the highest temperature in zone 528E (i.e., center region). Likewise, during liquid flow in the reverse direction, the first temperature is greater than the second temperature, which is greater than the third temperature, which is greater than the fourth temperature, resulting the highest temperature in zone 528A (i.e., edge region).

The FIG. 9 embodiment provides the ability to monotonically increase or decrease temperature along a radius of substrate 326 during plasma processing. For example, the temperature in each individual zone 528A-528E can be set such that the radial temperature profile is parabolic or inverse parabolic (i.e. monotonic).

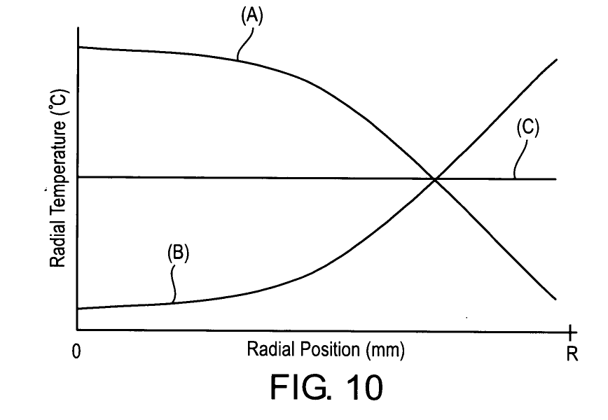

During plasma processing (e.g., plasma etching of semiconductors, metals or dielectrics; or deposition of conductive or dielectric materials) substrate support 300 with heat transfer member 320/420/520 has the ability to vary the center-to-edge radial temperature profile by up to 40° C., while maintaining an azimuthal temperature uniformity of ≦1° C., more preferably ≦0.5° C. Furthermore, such heat transfer members 320/420/520 provide the ability for either: (1) uniform temperature distribution; or (2) radially varying temperature distribution (e.g., hot edge or hot center), both of which are useful for step-changeable temperature control during plasma processing, to enable optimal multi-layer processing. FIG. 10 illustrates radial temperature as a function of radial position on a wafer with radius R for three exemplary center-to-edge temperature profiles during plasma processing with heat transfer members 320/420/520: (A) a center region hotter than an edge region; (B) a center region colder than an edge region; and (C) uniform temperature distribution completely across the wafer.

While the invention has been described in detail with reference to specific embodiments thereof, it will be apparent to those skilled in the art that various changes and modifications can be made, and equivalents employed, without departing from the scope of the appended claims.

What is claimed is:

1. A substrate support useful in a reaction chamber of a plasma processing apparatus, the substrate support comprising:
a base member;
a heat transfer member overlying the base member, the heat transfer member having multiple zones including at least a first zone with a first flow passage therein and a second zone with a second flow passage therein through which a liquid can be circulated to individually heat and cool the first and second zones of the heat transfer member;
an electrostatic chuck overlying the heat transfer member, the electrostatic chuck having a support surface for supporting a substrate in a reaction chamber of the plasma processing apparatus;
a source of cold liquid and a source of hot liquid in fluid communication with the first and second flow passages;
a valve arrangement operable to independently control temperature of the liquid in the first and second zones by adjusting a mixing ratio of the hot liquid to the cold liquid circulating in the first and second flow passages;
a controller controlling the valve arrangement to independently control the temperature in the first and second zones by adjusting the mixing ratio of the hot liquid to the cold liquid in the first and second flow passages.

2. The substrate support of claim 1, further comprising:
a first temperature sensor in the first zone and a second temperature sensor in the second zone, the temperature sensors adapted to measure a temperature in the first and second zones and supply input signals to the controller;
a thermal barrier separating the first and second zones; and
a bonding material between the heat transfer member and the base member, the bonding material having a thermal conductivity from about 0.1 W/m-K to about 4 W/m-K; and a thickness from about 1 mil to about 200 mils.

3. The substrate support of claim 1, wherein the source of cold liquid maintains the cold liquid at a temperature ≧−10° C.; and the source of hot liquid maintains the hot liquid at a temperature ≦150° C., wherein the hot liquid temperature is greater than the cold liquid temperature.

4. The substrate support of claim 2, wherein the heat transfer member is a circular plate; each zone is concentrically arranged at a different radial distance relative to a center of the circular plate; and the thermal barrier is an annular channel.

5. The substrate support of claim 4, where the annular channel is empty; or the annular channel is filled with epoxy or silicone or other materials with thermal conductivity from about 0.1 to about 4.0 W/m-K.

6. The substrate support of claim 4, wherein the annular channel extends through an entire thickness of the heat transfer member; or the annular channel extends through a partial thickness of the heat transfer member.

7. The substrate support of claim 2, wherein the bonding material is composed of silicone or epoxy and contains one or more filler materials, the filler materials including aluminum oxide, boron nitride, silicon oxide, aluminum or silicon; or the bonding material is composed of a metallic brazed joint.

8. The substrate support of claim 1, wherein the heat transfer member is composed of aluminum or an aluminum alloy; or the heat transfer member is composed of stainless steel, aluminum oxide or yttrium oxide.

9. A method of controlling an azimuthal temperature of a semiconductor substrate during plasma processing, comprising:
supporting the substrate on the substrate support of claim 1, wherein the substrate is in thermal contact with the multiple zones;
flowing the liquid through the first and second flow passages;
measuring a temperature of the first zone and increasing the temperature of the liquid flowing through the first flow passage if the temperature of the first zone is below a target temperature of the first zone by increasing the mixing ratio of the hot liquid to the cold liquid; or decreasing the temperature of the liquid flowing through the first flow passage if the temperature of the first zone is above the target temperature by decreasing the mixing ratio of the hot liquid to the cold liquid; and
measuring a temperature of the second zone and increasing the temperature of the liquid flowing through the second flow passage if the temperature of the second zone is below a target temperature of the second zone by increasing the mixing ratio of the hot liquid to the cold liquid; or decreasing the temperature of the liquid flowing through the second flow passage if the temperature of the second zone is above the target temperature by decreasing the mixing ratio of the hot liquid to the cold liquid;
wherein an azimuthal temperature difference within each zone is less than 5° C.

10. The method of claim 9, wherein the azimuthal temperature difference across the multiple zones is less than 0.5° C. and a radial temperature profile across the substrate is step-changeable between: (a) a uniform temperature completely across the substrate; or (b) a non-uniform temperature across the substrate, wherein a center region of the substrate is hotter than an edge region of the substrate or the center region of the substrate is colder than the edge region of the substrate.

11. The method of claim 9, wherein the target temperature of the first zone and the target temperature of the second zone are: (a) monotonically increasing or decreasing along a substrate radius; or (b) are non-monotonically increasing or decreasing along the substrate radius.

12. The method of claim 9, further comprising:
introducing a process gas into the reaction chamber;
energizing the process gas into a plasma state; and
processing the substrate with the plasma, wherein processing the substrate with the plasma includes: (a) plasma etching a layer of semiconductor material, metal or dielectric material; or (b) deposition of conductive or dielectric material.

13. A plasma processing apparatus comprising the semiconductor substrate support of claim 1, wherein the plasma processing apparatus is a plasma etcher adapted to etch semiconductor, metal or dielectric material; or a deposition chamber adapted to deposit conductive or dielectric material.

14. A substrate support useful in a reaction chamber of a plasma processing apparatus, the substrate support comprising:
a base member;
a heat transfer member overlying the base member, the heat transfer member having a first zone with a first flow passage and a second zone with a second flow passage, wherein the flow passages are adapted to circulate a liquid to individually heat and cool each zone of the heat transfer member;
a first common line in fluid communication with the first flow passage;
a second common line in fluid communication with the second flow passage;
a first valve in fluid communication with the first common line and a first supply line from a hot liquid source, the first valve operable to control an amount of flow of a hot liquid from the hot liquid source through the first common line;
a second valve in fluid communication with the first common line and a second supply line from a cold liquid source, the second valve operable to control an amount of flow of a cold liquid from the cold liquid source through the first common line;
a third valve in fluid communication with the second common line and the first supply line from the hot liquid source, the third valve operable to control an amount of flow of the hot liquid through the second common line;
a fourth valve in fluid communication with the second common line and the second supply line from the cold liquid source, the fourth valve operable to control an amount of flow of the cold liquid through the second common line;
a controller operable to independently control:
(a) the first valve and the second valve to adjust a first mixing ratio of the hot liquid to the cold liquid to the first flow passage; and
(b) the third valve and the fourth valve to adjust a second mixing ratio of the hot liquid to the cold liquid to the second flow passage; and
an electrostatic chuck overlying the heat transfer member, the electrostatic chuck having a support surface for supporting a substrate in a reaction chamber of the plasma processing apparatus.

15. The substrate support of claim 14, further comprising:
the heat transfer member having a third zone with a third flow passage, a fourth zone with a fourth flow passage and a fifth zone with a fifth flow passage;
a third common line in fluid communication with the third flow passage;
a fourth common line in fluid communication with the fourth flow passage;
a fifth common line in fluid communication with the fifth flow passage;
a fifth valve in fluid communication with the third common line and the first supply line from the hot liquid source, the fifth valve operable to control an amount of flow of the hot liquid through the third common line;
a sixth valve in fluid communication with the third common line and the second supply line from the cold liquid source, the sixth valve operable to control an amount of the flow of the cold liquid through the third common line;
a seventh valve in fluid communication with the fourth common line and first supply line from the hot liquid source, the seventh valve operable to control an amount of flow of the hot liquid through the fourth common line;
an eighth valve in fluid communication with the fourth common line and the second supply line from the cold liquid source, the eighth valve operable to control an amount of the flow of the cold liquid through the fourth common line;
a ninth valve in fluid communication with the fifth common line and the first supply line from the hot liquid source, the ninth valve operable to control an amount of flow of the hot liquid through the fifth common line;
an tenth valve in fluid communication with the fifth common line and the second supply line from the cold liquid source, the tenth valve operable to control an amount of the flow of the cold liquid through the fifth common line; and
the controller further operable to independently control:
(c) the fifth valve and the sixth valve to adjust a third mixing ratio of the hot liquid to the cold liquid to the third flow passage;
(d) the seventh valve and the eighth valve to adjust a fourth mixing ratio of the hot liquid to the cold liquid to the fourth flow passage; and
(e) the ninth valve and the tenth valve to adjust a fifth mixing ratio of the hot liquid to the cold liquid to the fifth flow passage.

16. The substrate support of claim 14, wherein the heat transfer member is a circular plate; and each zone is concentrically arranged at a different radial distance relative to a center of the circular plate.

17. The substrate support of claim 16, wherein the first flow passage, the second flow passage, the third flow passage, the fourth flow passage and the fifth flow passage are in fluid communication with a return line; and the return line is in fluid communication with the hot liquid source and/or the cold liquid source.

18. A substrate support useful in a reaction chamber of a plasma processing apparatus, the substrate support comprising:
a base member;
a heat transfer member overlying the base member, the heat transfer member having a first zone with a first flow passage and a second zone with a second flow passage, wherein the flow passages are adapted to circulate a liquid to individually heat and cool each zone of the heat transfer member;
a supply line in fluid communication with the first flow passage and a liquid source;
a first heating element along the supply line, the first heating element adapted to heat the liquid flowing from the liquid source to a first temperature before the liquid is circulated in the first flow passage;
a first transfer line in fluid communication with the first flow passage and the second flow passage, the first transfer line adapted to flow the liquid from the first flow passage to the second flow passage;
a second heating element along the first transfer line, the second heating element adapted to heat the liquid to a second temperature before circulating in the second flow passage;
a controller controlling each heating element to independently control the temperature of each zone by adjusting power to each heating element; and
an electrostatic chuck overlying the heat transfer member, the electrostatic chuck having a support surface for supporting a substrate in a reaction chamber of the plasma processing apparatus.

19. The substrate support of claim 18, further comprising:
the heat transfer member having a third zone with a third flow passage, a fourth zone with a fourth flow passage and a fifth zone with a fifth flow passage;
a second transfer line in fluid communication with the second flow passage and the third flow passage, the second transfer line adapted to flow liquid from the second flow passage to the third flow passage;
a third heating element along the second transfer line, the third heating element adapted to heat the liquid to a third temperature before circulating in the third flow passage;
a third transfer line in fluid communication with the third flow passage and the fourth flow passage, the third transfer line adapted to flow liquid from the third flow passage to the fourth flow passage; and
a fourth heating element along the third transfer line, the fourth heating element adapted to heat the liquid to a fourth temperature before circulating in the fourth flow passage;
a fourth transfer line in fluid communication with the fourth flow passage and the fifth flow passage, the fourth transfer line adapted to flow liquid from the fourth flow passage to the fifth flow passage; and
a fifth heating element along the fourth transfer line, the fifth heating element adapted to heat the liquid to a fifth temperature before circulating in the fifth flow passage; and
a return line in fluid communication with the fifth flow passage and the liquid source, the return line adapted to flow liquid from the fifth flow passage to the liquid source.

20. The substrate support of claim 18, further comprising, a temperature sensor in each zone, the temperature sensor adapted to measure a temperature in each zone and supply input signals to the controller; or wherein the first transfer line is adapted to flow the liquid from the first flow passage to the second flow passage in a forward or reverse direction.
